(19) United States
(12) Patent Application Publication
(10) Pub. No.: US 2025/0311556 A1
(43) Pub. Date: Oct. 2, 2025

(54) DISPLAY DEVICE AND DISPLAY PANEL

(71) Applicant: LG Display Co., Ltd., Seoul (KR)

(72) Inventors: MinSeob SONG, Jeonju-si (KR); ChangHeon KANG, Paju-si (KR)

(73) Assignee: LG Display Co., Ltd., Seoul (KR)

(21) Appl. No.: 19/027,815

(22) Filed: Jan. 17, 2025

(30) Foreign Application Priority Data
Mar. 27, 2024 (KR) 10-2024-0041564

(51) Int. Cl. H10K 59/122; H10K 59/38; H10K 59/40; H10K 102/00

(52) U.S. Cl. CPC H10K 59/122; H10K 59/38; H10K 59/40; H10K 2102/351

(57) ABSTRACT

A display device and a display panel are discussed. The display device can include a substrate having a display area and a non-display area, where the display area includes a plurality of sub-pixels. The display device can further include a first transistor disposed in the plurality of sub-pixels on the substrate, a first organic layer disposed on the first transistor, a connection electrode disposed on the first organic layer and connected to the first transistor, a second organic layer and a third organic layer disposed on the first organic layer and the connection electrode, and a light emitting element disposed on the second organic layer and the third organic layer. The light emitting element includes an anode connected to the connection electrode, an organic layer, and a cathode. The third organic layer overlaps the anode of the light emitting element.

### CROSS-REFERENCE TO RELATED APPLICATIONS

This application claims priority to Korean Patent Application No. 10-2024-0041564, filed in the Republic of Korea on Mar. 27, 2024, the entire contents of which is hereby expressly incorporated by reference into the present application.

### BACKGROUND

### Technical Field

The present disclosure relates to a display device and a display panel, more particularly, for example, without limitation, to an organic light emitting display device and an organic light emitting display panel for improving pixel shrinkage.

### Description of the Related Art

Currently, the field of display devices that visually display electrical information signals is developing rapidly. Research is being conducted to improve performance and features of the display devices, such as thinning, weight reduction, and low power consumption for the various display devices.

Representative display devices can include a liquid crystal display device (LCD), organic light emitting display device (OLED), etc.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventors of the present application have recognized the problems and disadvantages of the related art, e.g., pixel shrinkage defect that can occur in related display devices. Accordingly, an object to be achieved by the present disclosure is to provide an organic light emitting display device that can effectively addresses and minimizes pixel shrinkage.

Another object to be achieved by the present disclosure is to provide an organic light emitting display device capable of minimizing a distortion phenomenon that can be caused by external light reflection by flattening an anode.

Still another object to be achieved by the present disclosure is to provide an organic light emitting display device with improved color viewing angle characteristics.

Objects of the present disclosure are not limited to the above-mentioned objects, and other objects, which are not mentioned above, can be clearly understood by those skilled in the art from the following descriptions.

An organic light emitting display device according to an example embodiment of the present disclosure includes: a substrate including a display area and a non-display area, the display area including a plurality of sub-pixels, a first transistor disposed on the substrate in the plurality of sub-pixels, a first organic layer disposed on the first transistor, a connection electrode disposed on the first organic layer and connected to the first transistor, a second organic layer and a third organic layer disposed on the first organic layer and the connection electrode and a light emitting element disposed on the second organic layer and the third organic layer and including an anode connected to the connection electrode, an organic layer, and a cathode, in which the third organic layer overlaps the anode of the light emitting element, and the second organic layer can be disposed to surround a side surface of the third organic layer.

A display panel is provided according to an example embodiment of the present disclosure, the display panel is divided into a display area including a plurality of sub-pixels and a non-display area, the display panel comprising: a first transistor disposed in the plurality of sub-pixels; a first organic layer disposed on the first transistor; a connection electrode disposed on the first organic layer and connected to the first transistor; a second organic layer and a third organic layer disposed on the first organic layer and the connection electrode; and a light emitting element disposed on the second organic layer and the third organic layer and including an anode connected to the connection electrode, an organic layer, and a cathode, wherein the third organic layer overlaps the anode of the light emitting element, and wherein the second organic layer is disposed to surround a side surface of the third organic layer.

Other detailed matters of the example embodiments are included in the detailed description and the drawings.

According to an example embodiment of the present disclosure, it is possible to improve the pixel shrinkage.

According to an example embodiment of the present disclosure, it is possible to change the structure and disposition of the organic layer under the anode of the light emitting element to flatten the anode of the light emitting element.

According to an example embodiment of the present disclosure, it is possible to flatten the anode of the light emitting element to improve the rainbow moiré (mura) phenomenon caused by the external light reflection.

According to an example embodiment of the present disclosure, it is possible to dispose the convex organic layer under the anode of the light emitting element to improve the reflection characteristics and the color viewing angle characteristics.

The effects of the present disclosure are not limited to the aforementioned effects, and other effects, which are not mentioned above, will be apparently understood to a person having ordinary skill in the art from the following description.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure. The above and other aspects, features and other advantages of the present disclosure will be more clearly understood from the following detailed description taken in conjunction with the accompanying drawings, in which:

FIG. 1 is a plan view illustrating a schematic structure of an organic light emitting display device according to one or more embodiments of the present disclosure;

FIG. 2 is an equivalent circuit diagram illustrating a circuit configuration of one pixel constituting the organic light emitting display device according to an embodiment of the present disclosure;

FIG. 3 is a plan view illustrating sub-pixels disposed in a display area illustrated in FIG. 1;

FIG. 4 is a cross-sectional view taken along line A-A′ of FIG. 3;

FIG. 5 is a cross-sectional view taken along the line B-B′ of FIG. 1;

FIG. 6 is a cross-sectional view of an organic light emitting display device according to another example embodiment of the present disclosure; and

FIG. 7 is a cross-sectional view of an organic light emitting display device according to another example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers of elements and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “include,” “have,” “comprise,” “contain,” “constitute,” “make up of,” “formed of,” and “consist of” used herein are generally intended to allow other components to be added unless the terms are used with the term “only”. Any references to singular can include plural unless expressly stated otherwise.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Components are interpreted to include an ordinary error range even if not expressly stated.

When the position relation between two parts is described using the terms such as “on”, “above”, “over”, “below”, “under”, “beside”, “beneath”, “near”, “close to,” “adjacent to”, “on a side of”, “next”, one or more parts can be positioned between the two parts unless the terms are used with the term “immediately” or “directly”.

Spatially relative terms, such as “under,” “below,” “beneath”, “lower,” “over,” “upper” and the like, can be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

The word “exemplary” is used to mean serving as an example or illustration. Aspects are example aspects. “Embodiments,” “examples,” “aspects,” and the like should not be construed as preferred or advantageous over other implementations. An embodiment, an example, an exemplary embodiment, an aspect, or the like can refer to one or more embodiments, one or more examples, one or more example embodiments, one or more aspects, or the like, unless stated otherwise. Further, the term “can” encompasses all the meanings of the term “may.”

When an element or layer is disposed “on” another element or layer, another layer or another element can be interposed directly on the other element or therebetween.

When a temporal relationship is described, for example, when terms for temporal relationship of events such as “after”, “subsequently”, “next”, and “before” are used, there can also be the case in which the events are not continuous, unless “immediately” or “directly” is used.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

The term “at least one” should be understood as including all possible combinations which can be suggested from one or more relevant items. For example, the meaning of “at least one of a first item, a second item, or a third item” can be each one of the first item, the second item, or the third item and also be all possible combinations that can be suggested from two or more of the first item, the second item, and the third item.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Also, the source electrode in any one aspect of the present disclosure can be the drain electrode in another aspect of the present disclosure, and the drain electrode in any one aspect of the present disclosure can be the source electrode in another aspect of the present disclosure.

Hereinafter, embodiments of the present disclosure will be described with reference to the accompanying drawings. In the specification, in adding reference numerals for elements in each drawing, it should be noted that like reference numerals already used to denote like elements in other drawings are used for elements wherever possible. In addition, the dimension scales of constituent elements shown in the drawings can be different from actual dimension scales, for convenience of description. For example, the dimension scales of constituent elements shown in the drawings should not be interpreted to be the same as those shown in the drawings.

Hereinafter, a display device according to example embodiments of the present disclosure will be described in detail with reference to accompanying drawings. All the components of each display device according to all embodiments of the present disclosure are operatively coupled and configured.

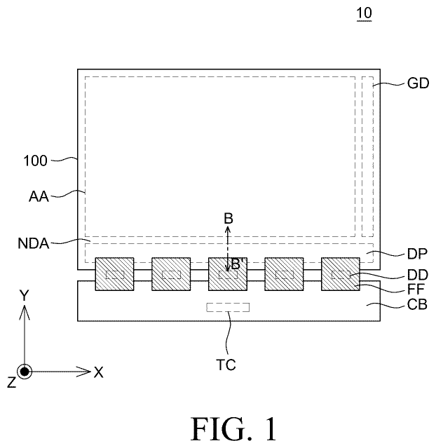

FIG. 1 is a plan view illustrating a schematic structure of an organic light emitting display device according to an example embodiment of the present disclosure. In FIG. 1, as an example, an X-axis represents a direction parallel to a scan line, a Y-axis represents a direction parallel to a data line, and a Z-axis represents a height direction of a display device. However, the present disclosure is not limited thereto, and covers other variations, for example, Y-axis can represent a direction parallel with a scan line, X-axis can represent a direction parallel with a data line, and Z-axis can represent a height direction of the display device.

Referring to FIG. 1, a display device 10 according to an example embodiment of the present disclosure includes a substrate 100, a gate (or scan) driver GD, a data pad unit DP, a source-driven integrated circuit DD, a flexible wiring film FF, a circuit board CB, and a timing controller TC.

The substrate 100 can include an insulating material or a material having flexibility. The substrate 100 can be made of glass, metal, plastic, or the like, but is not limited thereto. When the display device 10 is a flexible display device, the substrate 100 can be made of a flexible material such as plastic. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS). For example, the substrate 100 can include a transparent polyimide material, and the present disclosure is not limited thereto.

The substrate 100 can be divided into a display area (or active area) AA and a non-display area (or non-active area) NDA. The display area AA is an area where an image is displayed, and can be defined in most of the area including the center of the substrate 100, but is not limited thereto. Scan lines (or gate lines), data lines, and pixels are formed in the display area AA. The pixels include a plurality of sub-pixels, and the plurality of sub-pixels include the scan lines and the data lines, respectively.

The non-display area NDA is an area where an image is not displayed, and can be defined in an edge portion of the substrate 100 to surround a portion or the entirety of the display area AA. The non-display area NDA can be an area adjacent to the display area AA. Further, the non-display area NDA can be an area disposed adjacent to the display area AA and configured to surround the display area AA. The non-display area NDA can surround the display area AA entirely or only in part(s). However, the present disclosure is not limited thereto.

For example, the non-display area NDA can include a first non-display area located outside the display area AA in a first direction, a second non-display area located outside the display area AA in a second direction intersecting the first direction, a third non-display area located outside the display area AA in the opposite direction to the first direction, and a fourth non-display area located outside the display area AA in the direction opposite to the second direction.

For another example, a boundary area between the display area AA and the non-display area NDA can be bent so that the non-display area NDA can be located below the display area. In this case, when the user looks at the display device from the front, there can be little or no non-display area NDA visible to the user.

The gate driver GD and the data pad unit DP can be formed in the non-display area NDA.

The gate driver GD supplies the scan (or gate) signals to the scan lines according to a gate control signal input from a timing controller TC. The gate driver GD can be formed in the non-display area NDA on an outside of one side of the display area AA of the substrate 100 in a gate driver in panel (GIP) method. The GIP method refers to a structure in which the gate driver GD is formed directly on the substrate 100.

The source-driven integrated circuit DD supplies data signals to the data lines according to a data control signal input from the timing controller TC. The source-driven integrated circuit DD is manufactured as a driving chip to be mounted on a flexible wiring film FF, and can be attached to the data pad unit DP provided in the non-display area NDA on an outside of one side of the display area AA of the substrate 100 by a tape automated bonding (TAB) method. However, the present disclosure is not limited thereto.

The source-driven integrated circuit DD receives digital video data and a source control signal from the timing controller TC. The source-driven integrated circuit DD converts the digital video data into analog data voltages according to the source control signal and supplies the analog data voltages to the data lines. When the source-driven integrated circuit DD is manufactured as a chip, it can be mounted on the flexible wiring film FF by a chip on film (COF) method or a chip on plastic (COP) method. However, the present disclosure is not limited thereto.

Wirings connecting the data pad unit DP and the source-driven integrated circuit DD and wirings connecting the data pad unit DP and the circuit board CB can be formed on the flexible wiring film FF. The flexible wiring film FF is attached to the data pad unit DP using an anisotropic conducting film, so the wirings of the data pad unit DP and the flexible film FF can be connected.

The circuit board CB can be attached to the flexible wiring film FFs. A plurality of circuits implemented as the driving chips can be mounted on the circuit board CB. For example, the timing controller TC can be mounted on the circuit board CB. The circuit board CB can be a printed circuit board or a flexible printed circuit board.

The timing controller TC receives digital video data and a timing signal from an external system board through a cable of the circuit board CB. The timing controller TC generates a gate control signal for controlling an operation timing of the gate driver GD and a source control signal for controlling the source driving integrated circuits DD, based on the timing signal. The timing controller TC supplies the gate control signal to the gate driver GD and supplies the source control signal to the source driving integrated circuits DDs. Depending on the products, the timing controller TC can include the source driving integrated circuit DD and a single driving chip and mounted on the substrate 100. However, the present disclosure is not limited thereto.

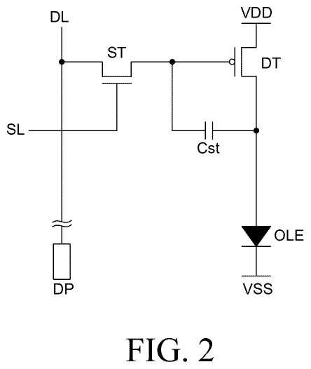

FIG. 2 is an equivalent circuit diagram illustrating a circuit configuration of one pixel constituting the organic light emitting display device according to an example embodiment of the present disclosure

Referring to FIG. 2, each pixel of the organic light emitting display device 10 includes a scan line SL, a data line DL, and a driving voltage line VDD. The data pad unit DP is disposed at an end of the data line DL. A scan pad can be disposed at the end of the scan line SL.

One pixel of the display device 10 includes a switching thin film transistor ST, a driving thin film transistor DT, an organic light emitting element OLE, and a storage capacitor Cst. A high potential voltage for driving the organic light emitting element OLE is applied to the driving voltage line VDD.

For example, the switching thin film transistor ST can be disposed at a portion where the scan line SL and the data line DL intersect. The switching thin film transistor ST includes a gate electrode SG, a source electrode, and a drain electrode. The gate electrode can be branched from the scan line SL or can be a portion of the scan line SL. The source electrode is connected to the data line, and the drain electrode is connected to the driving thin film transistor DT. The switching thin film transistor ST has a function of selecting a pixel to be driven by applying the data signal to the driving thin film transistor DT.

The driving thin film transistor DT has a function of driving the organic light emitting element OLE of the pixel selected by the switching thin film transistor ST. The driving thin film transistor DT includes a gate electrode, a source electrode, and a drain electrode. The gate electrode is connected to the drain electrode of the switching thin film transistor ST. The source electrode is connected to the driving voltage line VDD, and the drain electrode is connected to an anode of the organic light emitting element OLE. The storage capacitor Cst can be formed between the drain electrode of the driving thin film transistor DT and the anode of the organic light emitting element OLE.

The driving thin film transistor DT is disposed between the driving voltage line VDD and the organic light emitting element OLE. The driving thin film transistor DT adjusts the amount of current flowing from the driving voltage line VDD to the organic light emitting element OLE according to the magnitude of the voltage of the gate electrode of the driving thin film transistor DT that is connected to the drain electrode of the switching thin film transistor ST.

Active layers of thin-film transistors can be formed of a semiconductor material, such as an oxide semiconductor, amorphous semiconductor, or polycrystalline semiconductor, but is not limited thereto.

The oxide semiconductor material can have an excellent effect of preventing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

In FIG. 2, each of the subpixels has 2T(Transistor)1C(Capacitor) structure including two transistors DT and ST and one capacitor Cst, but not limited thereto. Each of the subpixels can further include a compensation circuit CC. In this case, various structures such as 4T2C, 5T2C, 6T1C, 6T2C, 7T1C, 7T2C, and the like can be provided.

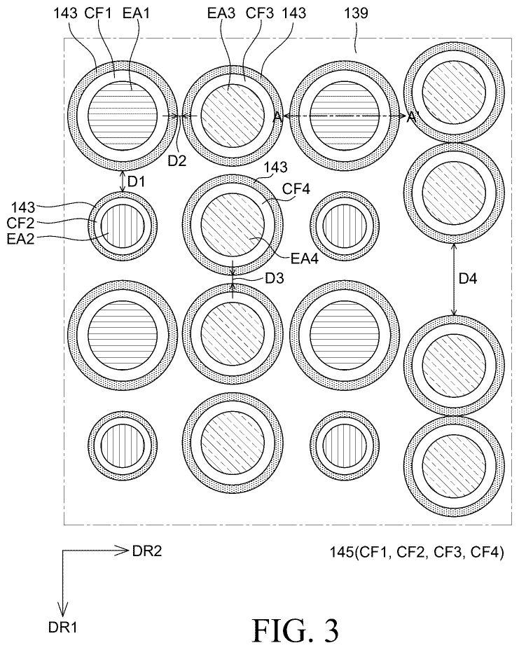

FIG. 3 is a plan view illustrating sub-pixels disposed in the display area illustrated in FIG. 1.

Referring to FIG. 3, the display area AA displays an image through unit pixels disposed in a matrix form. The unit pixels are composed of a red (R) sub-pixel, a green (G) sub-pixel, and a blue (B) sub-pixel, or composed of a red (R) sub-pixel, a green (G) sub-pixel, a blue (B) sub-pixel, and a white (W) sub-pixel. However, the present disclosure is not limited thereto. A plurality of subpixels SP constituting unit pixel can be variously modified in colors and configurations, as necessary.

For example, each of the plurality of subpixels SP can emit light having different wavelengths from each other. For example, the plurality of subpixels SP can include red, green, and blue subpixels, in which the red, green, and blue subpixels can be disposed in a repeated manner. Alternatively, the plurality of subpixels SP can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

For example, as illustrated in FIG. 3, the color filter CF can be disposed in the red (R) sub-pixel, the green (G) sub-pixel, and the blue (B) sub-pixel, and can be disposed spaced apart from each other.

For convenience of description, FIG. 3 conceptually illustrates a form in which light emitting areas EA1, EA2, EA3, and EA4, a touch unit 139, a black matrix 143, and color filters CF1, CF2, CF3, and CF4 are disposed on a plane, regardless of the stacking order.

In an example embodiment, the first light emitting area EA1, the second light emitting area EA2, the third light emitting area EA3, and the fourth light emitting area EA4 can be defined by the exposed anodes 121 of each of the light emitting elements. For example, the light emitting area can also be defined by areas corresponding to each light emitting layer, an opening area of a bank, etc.

In an example embodiment, the second light emitting area EA2 can be adjacent to the first light emitting area EA1 in a first direction DR1, and the third light emitting area EA3 can be adjacent to the first light emitting area EA1 in a second direction DR2. The second direction DR2 can be a direction intersecting the first direction DR1. For example, the second direction DR2 can be a direction perpendicular to the first direction DR1. The fourth light emitting area EA4 can be adjacent to the second light emitting area EA2 in the second direction DR2, and adjacent to the third light emitting area EA3 in the first direction DR1.

The first light emitting area EA1 can correspond to a first sub-pixel, and the second light emitting area EA2 can correspond to a second sub-pixel. The third light emitting area EA3 and the fourth light emitting area EA4 can correspond to a third sub-pixel. Here, the first sub-pixel, the second sub-pixel, and the third sub-pixel can be driven by separate pixel circuits, respectively. The third light emitting area EA3 and the fourth light emitting area EA4 can be connected to and controlled by one sub-pixel pixel circuit.

In an example embodiment, the first light emitting area EA1, the second light emitting area EA2, the third light emitting area EA3, and the fourth light emitting area EA4 can have a circular shape when viewed on a plane. The first light emitting area EA1, the second light emitting area EA2, the third light emitting area EA3, and the fourth light emitting area EA4 can have, but is not limited to, various shapes, such as a circular shape, and a polygonal shape, such as a square shape, a trapezoidal shape, and other polygonal shapes, when viewed on a plane. However, when boundaries of the first light emitting area EA1, the second light emitting area EA2, the third light emitting area EA3, and the fourth light emitting area EA4 include a straight portion, a flare defect in which light spreads in a direction perpendicular to the planar surface of the straight portion can be recognized. In order to minimize or reduce the flare defect, the first light emitting area EA1, the second light emitting area EA2, the third light emitting area EA3, and the fourth light emitting area EA4 can be formed to have a circular shape as much as possible.

In an example embodiment, the areas of at least two of the first light emitting area EA1, the second light emitting area EA2, the third light emitting area EA3, and the fourth light emitting area EA4 can be different. The areas of the light emitting areas can be determined by reflecting the life characteristics of the light emitting elements. For example, an effective area of a light emitting area of a light emitting element having a relatively short life can be larger than an area of a light emitting area of a light emitting element having a relatively long life. Accordingly, the color characteristics of the display device according to the usage time can be maintained uniformly for a long time.

In an example embodiment, the first light emitting area EA1 can emit light of a first color, the second light emitting area EA2 can emit light of a second color, and the third light emitting area EA3 and the fourth light emitting area EA4 can emit light of a third color. For example, the first light emitting area EA1 can emit green light, the second light emitting area EA2 can emit red light, and the third light emitting area EA3 and the fourth light emitting area EA4 can emit blue light. However, the present disclosure is not limited thereto.

The lifespan of the red light emitting element can be longer than that of the green light emitting element and the blue light emitting element, and the lifespan of the green light emitting element can be longer than that of the blue light emitting element.

In an example embodiment, the area of the first light emitting area EA1, which has a relatively shorter lifespan, can be larger than that of the second light emitting area EA2, which has the longest lifespan. The third light emitting area EA3 and the fourth light emitting area EA4, which are the light emitting areas that emit blue light, can maintain a circular shape, and a total area of the third light emitting area EA3 and the fourth light emitting area EA4 can be larger than an area of the first light emitting area EA1.

In other words, the total area of the third light emitting area EA3 and the fourth light emitting area EA4, which emit the light of third color (e.g., blue) within a first pixel PX1, can be larger than each of the area of the first light emitting area EA1 and the area of the second light emitting area EA2.

According to an example embodiment, the area of the third light emitting area EA3 and the area of the fourth light emitting area EA4 that emit the same color can be same or substantially the same.

A distance between the light emitting areas can be determined according to the area of the light emitting areas and the spatial constraints in which they can be disposed. In an example embodiment, a distance D1 (hereinafter, the first distance D1 also has the same meaning) between the first light emitting area EA1 and the second light emitting area EA2 can be longer than a distance D2 (hereinafter, a second distance D2 also has the same meaning) between the first light emitting area EA1 and the third light emitting area EA3.

In addition, the distance D1 between the first light emitting area EA1 and the second light emitting area EA2 can be longer than a distance D3 (hereinafter, the third distance D3 also has the same meaning) between the third light emitting area EA3 and the fourth light emitting area EA4 of pixels adjacent to each other.

According to an example embodiment, a distance D4 (hereinafter, a fourth distance D4 also has the same meaning) between the fourth light emitting area EA4 and the third light emitting area EA3 can be different from the third distance D3. For example, the disposition of the light emitting areas can be designed such that the fourth distance D4 is shorter than the third distance D3.

A touch layer 139 including metal can be disposed on the light emitting elements, and a black matrix 143 having an opening can be disposed on the touch layer 139. The black matrix 143 can suppress color mixing between adjacent sub-pixels and/or light emitting areas. An area where the black matrix 143 is disposed can be a non-light emitting area.

The black matrix 143 can include openings that overlap each of the first to fourth light emitting areas EA1, EA2, EA3, and EA4. Each of the openings can be larger than the areas of each of the first to fourth light emitting areas EA1, EA2, EA3, and EA4 corresponding thereto. For example, the black matrix 143 can be formed by spacing the first to fourth light emitting areas EA1, EA2, EA3, and EA4 apart by a predetermined interval. Accordingly, a range in which light output from the first to fourth light emitting areas EA1, EA2, EA3, and EA4 is shielded by the black matrix 143 can be reduced, and a viewing angle can be improved.

The color filters CF1, CF2, CF3, and CF4 can be filled in the openings of the black matrix 143. The first color filter CF1 can overlap the first light emitting area EA1 and cover the entire first light emitting area EA1. The second color filter CF2 can overlap the second light emitting area EA2 and cover the entire second light emitting area EA2. The third color filter CF3 can overlap the third light emitting area EA3 and cover the entire third light emitting area EA3. The fourth color filter CF4 can overlap the fourth light emitting area EA4 and cover the entire fourth light emitting area EA4.

For example, in the patterns representing the first to fourth light emitting areas EA1, EA2, EA3, and EA4 in FIG. 3, respectively, it can be understood that each of the first to fourth color filters CF1, CF2, CF3, and CF4 and each of the first to fourth light emitting areas EA1, EA2, EA3, and EA4 overlap each other, respectively. For example, the first color filter CF1 and the first light emitting area EA1 overlap each other, the second color filter CF2 and the second light emitting area EA2 overlap each other, the third color filter CF3 and the third light emitting area EA3 overlap each other, and the fourth color filter CF4 and the fourth light emitting area EA4 overlap each other, and the present disclosure is not limited thereto.

In an example embodiment, each of the first to fourth color filters CF1, CF2, CF3, and CF4 can have a larger area than each of the first to fourth light emitting areas EA1, EA2, EA3, and EA4. The viewing angle can be increased by the disposition structure of the color filters CF1, CF2, CF3, and CF4 and the black matrix 143 described above.

According to an example embodiment, some of the first to fourth color filters CF1, CF2, CF3, and CF4 can overlap with the black matrix 143.

The first color filter CF1 can transmit light of a first color, the second color filter CF2 can transmit light of a second color, and the third and fourth color filters CF3 and CF4 can transmit light of a third color. However, the present disclosure is not limited thereto.

In this way, considering the flare defect, the lifespan of the light emitting element, the viewing angle, etc., the planar surface shape, area, location, etc., of the light emitting area are determined, so the black matrices 143 having various widths can be formed between the light emitting areas.

As described above, in the display device 10 according to an example embodiment of the present disclosure, the color filters CF1, CF2, CF3, and CF4 are disposed on the touch layer 139. Accordingly, the display device 10 can include the circular light emitting areas EA1 to EA4 for minimizing the flare defect, and can include a structure for minimizing the area where the black matrix 143 is disposed between the light emitting areas for securing the maximum viewing angle.

Each sub-pixel includes at least one of a thin film transistor having an oxide semiconductor layer and a thin film transistor having a polycrystalline semiconductor layer. The thin film transistor having the oxide semiconductor layer and the thin film transistor having the polycrystalline semiconductor layer have higher electron mobility than a thin film transistor having an amorphous semiconductor layer, thereby enabling the high resolution and low power implementation.

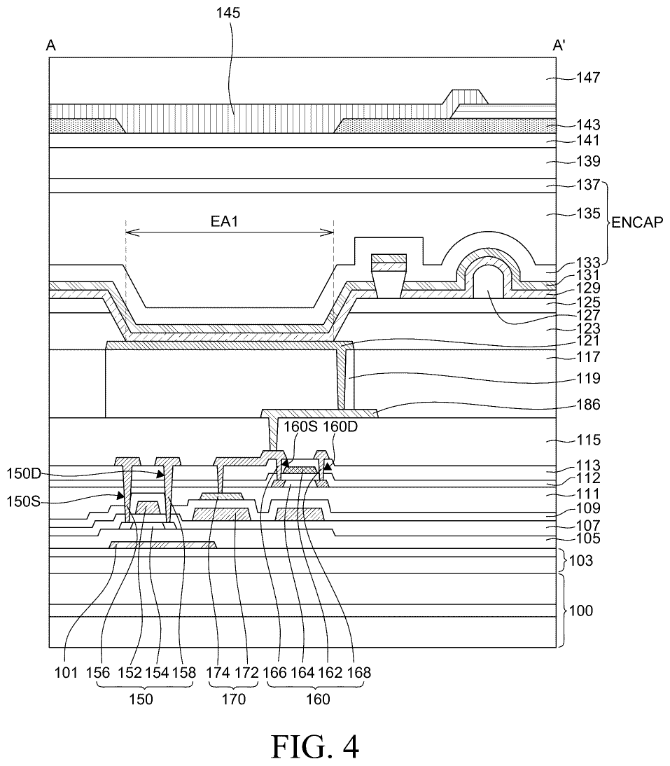

FIG. 4 is a cross-sectional view taken along line A-A′ of FIG. 3. Particularly, FIG. 4 schematically illustrates a cross-section centered on the thin film transistor and the sub-pixel area to describe the display device 10 according to an example embodiment of the present disclosure.

Referring to FIG. 4, a substrate 100 is a supporting member for supporting other components of the display device 10 and can be made of an insulating material. For example, the substrate 100 can be made of glass, resin, or the like. In addition, the substrate 100 can be made of a polymer or plastic such as polyimide (PI), or can be made of a material with flexibility. The substrate 100 can be a multi-substrate formed as a single layer or a multilayer.

A lower buffer layer 103 can be disposed on the substrate 100. The lower buffer layer 103 delays the diffusion of moisture or oxygen that penetrates into the substrate 100. The lower buffer layer 103 is formed by alternately stacking silicon nitride (SiNx) and silicon oxide (SiOx) at least once. For example, the lower buffer layer 103 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. However, the lower buffer layer 103 can be excluded in accordance with the structure or properties of the display device.

A lower protective metal 101 can be disposed on the lower buffer layer 103. A width of the lower protective metal 101 can be formed wider than that of the gate electrode 152 and the polycrystalline semiconductor layer 154. Therefore, the gate electrode 152 and the polycrystalline semiconductor layer 154 can be covered by the lower protective metal 101.

An upper buffer layer 105 can be disposed above the lower buffer layer 103 and the lower protective metal 101. The upper buffer layer 105 protects the polycrystalline semiconductor layer 154 and performs the function of blocking various types of defects introduced from the substrate 100. The upper buffer layer 105 can be made of amorphous silicon (a-Si), silicon nitride (SiNx), silicon oxide (SiOx), etc. For example, the upper buffer layer 105 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the present disclosure is not limited thereto. However, the upper buffer layer 105 can be excluded in accordance with the structure or properties of the display device.

The first thin film transistor 150 can be disposed above the upper buffer layer 105. The first thin film transistor 150 includes a gate electrode 152, a polycrystalline semiconductor layer 154, a source electrode 156, and a drain electrode 158.

The gate electrode 152 and the polycrystalline semiconductor layer 154 can overlap each other with a first gate insulating layer 107 therebetween. The first gate insulating layer 107 can be formed as a single layer made of an inorganic material or a multilayer made of different inorganic materials. For example, the first gate insulating layer 107 can be formed as a single layer of any one of a silicon oxide (SiOx) film, a silicon nitride (SiNx) film, and a silicon oxynitride (SiON) film, or a multilayer thereof. For example, the first gate insulating layer 107 can be formed by inorganic film in a single layer or in multiple layers, for example, the inorganic film in a single layer can be a silicon oxide (SiOx) film, a silicon nitride (SiNx) film or silicon oxynitride (SiON) film, and inorganic films in multiple layers can formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The gate electrode 152 is formed on the first gate insulating layer 107. The gate electrode 152 overlaps a channel region of the polycrystalline semiconductor layer 154 with the first gate insulating layer 107 therebetween. The gate electrode 152 can be formed as a single layer or multilayer made of any one of molybdenum (Mo), aluminum (Al), chromium (Cr), gold (Au), titanium (Ti), nickel (Ni), neodymium (Nd), and copper (Cu), or alloys thereof, but is not limited thereto.

A lower capacitor electrode 172 is disposed on the same layer as the gate electrode 152. The lower capacitor electrode 172 can be made of the same material as the gate electrode 152. However, the present disclosure is not limited thereto, the lower capacitor electrode 172 can be made of a different material from the gate electrode 152, and the lower capacitor electrode 172 can also be disposed on a different layer from the gate electrode 152. The lower capacitor electrode 172 overlaps an upper capacitor electrode 174 with the first insulating layer 109 interposed therebetween. The storage capacitor Cst 170 is formed by overlapping the lower capacitor electrode 172 and the upper capacitor electrode 174 with the first insulating layer 109 interposed therebetween, as illustrated in FIG. 4.

An upper portion of the first insulating layer 109 is stacked disposed in the order of an upper buffer layer 111, a second gate insulating layer 112, and a second insulating layer 113. A first source contact hole 150S and a first drain contact hole 150D are disposed above the second insulating layer 113.

The source electrode 156 is connected to a source region of the polycrystalline semiconductor layer 154 through the first source contact hole 150S that penetrates through the first gate insulating layer 107, the first insulating layer 109, the upper buffer layer 111, the second gate insulating layer 112, and the second insulating layer 113. The drain electrode 158 faces the source electrode 156 and is connected to a drain region of the polycrystalline semiconductor layer 154 through the first drain contact hole 150D penetrating through the first gate insulating layer 107, the first insulating layer 109, the upper buffer layer 111, the second gate insulating layer 112, and the second insulating layer 113. The polycrystalline semiconductor layer 154 has higher mobility than the amorphous semiconductor layer and the oxide semiconductor layer 164, so that it has low energy consumption and excellent reliability, and is therefore suitable for application to the gate driver GD that drives the switching transistor ST and the scan line SL of each sub-pixel.

After the process of forming the polycrystalline semiconductor layer 154 of the first thin film transistor 150, the oxide semiconductor layer 164 of the second thin film transistor 160 is formed. For example, the oxide semiconductor layer 164 is disposed above the polycrystalline semiconductor layer 154. Accordingly, since the oxide semiconductor layer 164 is not exposed to the polycrystalline semiconductor layer 154 process, damage to the oxide semiconductor layer 164 can be suppressed, thereby improving reliability.

The second thin film transistor 160 is disposed on the substrate 100 so as to be spaced apart from the first thin film transistor 150. The second thin film transistor 160 has a gate electrode 162, an oxide semiconductor layer 164, a source electrode 166, and a drain electrode 168.

The oxide semiconductor layer 164 is formed on the upper buffer layer 111 to overlap the gate electrode 162, thereby forming a channel between the source electrode 166 and the drain electrode 168. The oxide semiconductor layer 164 is formed of an oxide including at least one metal selected from Zn, Cd, Ga, In, and Sn. The second thin film transistor 160 including the oxide semiconductor layer 164 has the advantages of higher charge mobility and lower leakage current characteristics than the first thin film transistor 150 including the polycrystalline semiconductor layer 154, and therefore is preferably applied to the switching and driving thin film transistors ST and DT that have a short on time and a long off time.

The source electrode 166 and the drain electrode 168 can be a single layer or multilayer made of one of molybdenum (Mo), aluminum (Al), chromium (Cr), gold (Au), titanium (Ti), nickel (Ni), neodymium (Nd), and copper (Cu) or alloys thereof on the second gate insulating layer 112, but are not limited thereto.

The source electrode 166 is connected to the source region of the oxide semiconductor layer 164 through the second source contact hole 160S that penetrates through the second gate insulating layer 112 and the second insulating layer 113, and the drain electrode 168 is connected to the drain region of the oxide semiconductor layer 164 through the second drain contact hole 160D that penetrates through the second gate insulating layer 112 and the second insulating layer 113. In addition, the source electrode 166 and the drain electrode 168 are formed to face each other with the channel region of the oxide semiconductor layer 164 interposed therebetween.

A first organic layer 115 is disposed on the second insulating layer 113. The first organic layer 115 can flatten an upper portion of the second insulating layer 113. The first organic layer 115 can be made of an organic insulating material. For example, the first organic layer 115 can be made of at least one selected from a polyacrylates resin, an epoxy resin, a phenolic resin, a polyamides resin, a polyimides resin, an unsaturated polyesters resin, a polyphenyleneethers resin, a polyphenylenesulfides resin, and benzocyclobutene (BCB), and the present disclosure is not limited thereto.

A connection electrode 186 is disposed on the first organic layer 115. The connection electrode 186 is connected to the source electrode 166 of the second thin film transistor 160 through a contact hole disposed in the first organic layer 115.

A second organic layer 117 and a third organic layer 119 are disposed on the first organic layer 115 and the connection electrode 186. The second organic layer 117 and the third organic layer 119 can flatten an upper portion of the first organic layer 115. The third organic layer 119 can be disposed to overlap the anode 121 under the anode 121, and the second organic layer 117 can be disposed to surround a side surface of the third organic layer 119. Accordingly, the third organic layer 119 can overlap the anode 121, while the second organic layer 117 may not overlap the anode 121. In this case, the third organic layer 119 can be disposed to overlap the entire lower portion of the anode 121, and can be disposed to have a width equal to or greater than that of the anode 121.

The second organic layer 117 can be made of an organic insulating material, and can be made of the same material as the first organic layer 115, but is not limited thereto. For example, the second organic layer 117 can be made of at least one selected from a polyacrylates resin, an epoxy resin, a phenolic resin, a polyamides resin, a polyimides resin, an unsaturated polyesters resin, a polyphenyleneethers resin, a polyphenylenesulfides resin, and benzocyclobutene (BCB), and the present disclosure is not limited thereto. Alternatively, the second organic layer 117 can be made of a different material from the first organic layer 115, for example, the first organic layer 115 can be made of one selected from a polyacrylates resin, an epoxy resin, a phenolic resin, a polyamides resin, a polyimides resin, an unsaturated polyesters resin, a polyphenyleneethers resin, a polyphenylenesulfides resin, and benzocyclobutene (BCB), and the second organic layer 117 can be made of another one selected from a polyacrylates resin, an epoxy resin, a phenolic resin, a polyamides resin, a polyimides resin, an unsaturated polyesters resin, a polyphenyleneethers resin, a polyphenylenesulfides resin, and benzocyclobutene (BCB).

The third organic layer 119 can be made of a material having a lower viscosity or a higher curing temperature than the first organic layer 115 and the second organic layer 117. When a material having a lower viscosity or a higher curing temperature is applied, the flatness can increase. Accordingly, it is possible to improve the moiré (mura) phenomenon that reduces the display quality, such as rainbow moiré. When a step occurs in the anode 121 due to a component disposed under the anode 121, a light distortion phenomenon due to external light can occur. In this case, the moiré phenomenon can occur due to the light interference phenomenon caused by the mutual interference between the regular pattern shape of reflected light and the regularly disposed anodes. This moiré phenomenon affects the image quality characteristics, and a persistent pattern phenomenon can remain, causing the problem of visibility. The moiré phenomenon is expressed as a rainbow moiré phenomenon under the external light, further reducing visibility. The third organic layer 119 is disposed in a plurality of holes of the second organic layer 117, and is disposed in a form in which the third organic layer 119 is surrounded by the second organic layer 117. By disposing the third organic layer 119 under the anode 121, it is possible to slim the thickness of the display device, and by flattening the area where the anode 121 is disposed, it is possible to improve the moiré phenomenon.

The anode 121 is disposed on the third organic layer 119. The anode 121 is formed as a multilayer structure including a transparent conductive film and an opaque conductive film having high reflection efficiency. The transparent conductive film is made of a material having a relatively high work function value, such as indium-tin-oxide (ITO) or indium-zinc-oxide (IZO), and the opaque conductive film is made of a single layer or multilayer structure including Al, Ag, Cu, Pb, Mo, Ti, or alloys thereof. For example, the anode 121 is formed with a structure in which a transparent conductive film, an opaque conductive film, and a transparent conductive film are sequentially stacked, or a structure in which a transparent conductive film and an opaque conductive film are sequentially stacked. The anode 121 is disposed on the third organic layer 119 so that it overlaps not only the light emitting area provided by the first bank 123 but also the circuit area in which the first and second thin film transistors 150 and 160 and the storage capacitor Cst 170 are disposed, thereby increasing the light emitting area.

The light emitting layer 129 is formed on the anode 121. The light emitting layer 129 can be an organic light emitting layer including an organic material. In this case, the light emitting element can be an organic light emitting diode (OLED). However, the light emitting layer can include an inorganic material. In this case, the light emitting element ED can be an inorganic light emitting element. Meanwhile, in addition to the emitting layer 129, other layers such as a hole transport layer, a hole injection layer, an electron transport layer, and an electron injection layer can also be disposed between the anode 121 and the cathode 131. However, the present disclosure is not limited thereto.

The first bank 123 and the second bank 125 are formed to expose the anode 121. By exposing the anode 121, the light emitting area EA1 can be formed. The first bank 123 can be made of an opaque material (e.g., black material) to suppress the optical interference between adjacent sub-pixels. The second bank 125 can be made of a transparent material. The first bank 123 and the second bank 125 can include, but is not limited to, a light-shielding material made of at least one of a color pigment, an organic black material, and carbon.

Meanwhile, the first bank 123 and the second bank 125 can be formed as separate configurations, but can also be formed integrally to form one bank. For example, the first bank 123 and the second bank 125 illustrated in FIG. 4 can be integrated as one bank and implemented.

The first bank 123 and the second bank 125 can be disposed at a boundary between the plurality of subpixels SP and suppress a color mixture of light beams from the plurality of subpixels SP. The first bank 123 and the second bank 125 can cover the edge of each of the anodes 121 and can be formed to expose a portion of each of the anodes 121. Accordingly, the first bank 123 and the second bank 125 can prevent a current from being concentrated at an end of each of the anodes 121 so that it is possible to prevent a deterioration of light emitting efficiency.

A plurality of spacers 127 are disposed on the second bank 125 so as to be disposed between adjacent color filters 145. The spacers 127 can have a rectangular shape on a planar surface. However, the spacer 127 can have, but is not limited to a polygonal shape such as a square shape, a trapezoidal shape and other polygonal shapes, a circular shape, an oval shape, or a crescent shape in a planar surface. In addition, some of the plurality of spacers 127 can have an inverted taper shape in a cross-sectional view, and other some can have a regular taper shape in a cross-sectional view. For example, the spacer 127 can have an inverse trapezoidal shape or a regular trapezoidal shape in a cross-sectional view. The spacer 176 having the inverted taper shape can have an effect of controlling lateral current.

The plurality of spacers 127 can include a base resin and a black material. The base resin can be at least one selected from a cardo-based resin, an epoxy-based resin, an acrylate-based resin, a siloxane-based resin, and polyimide, but is not limited thereto. The black material can be a black pigment selected from a carbon-based pigment, a metal oxide-based pigment, and an organic pigment. For example, the carbon-based pigment can be carbon black. For example, the metal oxide-based pigment can include, but is not limited to, titanium black (TiNxOy), a Cu—Mn—Fe-based black pigment, and the like. For example, the organic pigment can be selected from, but is not limited to, lactam black, perylene black, and aniline black. In addition, an RGB black pigment including a red pigment, a blue pigment, and a green pigment can be used as the black material. However, the present disclosure is not limited thereto.

The cathode 131 is formed on an upper surface and a side surface of the light emitting layer 129 so as to face the anode 121 with the light emitting layer 129 therebetween. When applied to a top-emitting organic light emitting display device, the cathode 131 is made of a transparent conductive film such as indium-tin-oxide (ITO) or indium-zinc-oxide (IZO). Meanwhile, the cathode 131 can be made of a semi-transmissive conductive material such as magnesium Mg, silver Ag, or an alloy of magnesium Mg and silver Ag. When the cathode 131 is formed of a semi-transmissive metal material, a light emission efficiency can be increased by a microcavity.

An encapsulation part ENCAP can be disposed on the cathode 131. For example, the encapsulation part ENCAP has a structure in which inorganic encapsulation layers and organic encapsulation layers are alternately stacked, such that the encapsulation part ENCAP can protect the light-emitting element while inhibiting moisture or oxygen from penetrating into the light-emitting element. For example, the encapsulation part ENCAP can have a multi-insulating film structure in which organic films and inorganic films are stacked alternately. The inorganic film can block permeation of moisture or oxygen. The organic film can planarize a surface of the inorganic film. When the organic film and the inorganic film are stacked in multiple layers, a movement path of moisture or oxygen can be longer than that of a single layer, thereby effectively blocking the permeation of moisture and oxygen affecting the light emitting layer. The encapsulation part ENCAP can be formed by sequentially stacking a first inorganic encapsulation layer 133, a first organic encapsulation layer 135, and a second inorganic encapsulation layer 137. The encapsulation part ENCAP can further include one or more organic encapsulation layers and/or at least one inorganic encapsulation layer.

The first inorganic encapsulation layer 133 and the second inorganic encapsulation layer 137 can be made of an inorganic insulating material capable of low-temperature deposition, such as silicon nitride (SiNx), silicon oxide (SiOx), silicon oxynitride (SiON), or aluminum oxide (Al₂O₃), but not limited thereto.

The first organic encapsulation layer 135 can be made of an organic insulating material, such as acrylic resin, epoxy resin, polyimide, polyethylene, or silicon oxycarbon (SiOC), but not limited thereto.

Alternatively, the encapsulation part ENCAP includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer can serve to block the penetration of moisture or oxygen. The first inorganic encapsulation layer, the second inorganic encapsulation layer, and the third inorganic encapsulation layer can be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer can each have a larger thickness than each of the first inorganic encapsulation layer, the second inorganic encapsulation layer, and the third inorganic encapsulation layer in order to adsorb or block particles that can be produced during a process of manufacturing the display device. The first organic encapsulation layer and the second organic encapsulation layer can fill cracks that can be formed in the first inorganic encapsulation layer and the second inorganic encapsulation layer. The first organic encapsulation layer and the second organic encapsulation layer can planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer can planarize an upper portion of the first inorganic encapsulation layer by covering particles on the first inorganic encapsulation layer. For example, the second organic encapsulation layer can planarize an upper portion of the second inorganic encapsulation layer by covering particles on the second inorganic encapsulation layer. The first organic encapsulation layer and the second organic encapsulation layer can be made of an organic material, and for example, epoxy polymer, acrylic polymer, or the like can be used. However, the present disclosure is not limited thereto.

Meanwhile, the encapsulation part ENCAP is not limited to three or five layers, for example, n layers alternately stacked between inorganic encapsulation layer and organic encapsulation layer (where n is an integer greater than 3) can be included.

The touch layer 139, a protective layer 141, a black matrix 143, a color filter 145, and an overcoat layer 147 can be sequentially stacked above the encapsulation part ENCAP.

The protective layer 141 disposed on the touch layer 139 can be formed to suppress damage to the touch layer 139 during the process of forming the color filter 145 and the black matrix 143. The protective layer 141 can be an inorganic insulating layer. For example, the protective layer 141 can include an inorganic material such as silicon nitride (SiNx), silicon oxide (SiOx), aluminum oxide (AlOx), or the like.

The black matrix 143 can be disposed on the protective layer 141. The black matrix 143 can be formed by mixing a black material into a base resin. The base resin can be at least one selected from an epoxy-based resin, an acrylate-based resin, a siloxane-based resin, and polyimide, but is not limited thereto. In addition, the black material can be formed from any one of a black-based pigment or a black-based dye. The black matrix 143 can be disposed to be spaced apart from the light emitting area EA1 when viewed on a planar surface. For example, the opening of the black matrix 143 can overlap the light emitting area EA1 and be formed wider than the light emitting area EA1.

The color filter 145 and the black matrix 143 can be formed directly on the protective layer 141. The overcoat layer 147 can be disposed on the color filter 145, and a cover glass can be disposed on the overcoat layer 147.

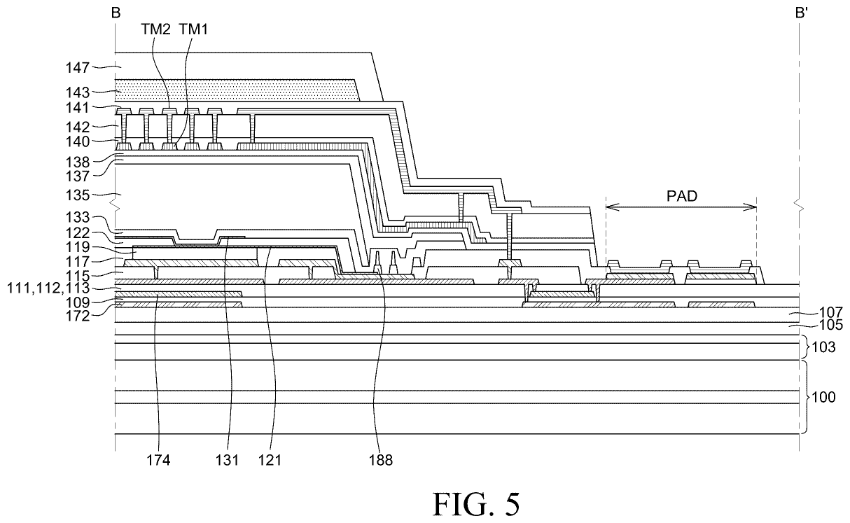

FIG. 5 is a cross-sectional view taken along the line B-B′ of FIG. 1. Particularly, FIG. 5 is a cross-sectional view corresponding to an outer region connected to a pad PAD of the display device 10. In FIG. 5, descriptions of contents overlapping with those described with reference to FIG. 4 will be omitted or briefly provided.

Referring to FIG. 5, the third organic layer 119 can be disposed on the entire lower portion of the anode 121. By disposing the third organic layer 119, which has a higher flatness than the first and second organic layers 115 and 117, under the anode 121, the anode region can be flattened, thereby improving the moiré phenomenon.

A dam 188 can be formed to suppress the first, second, and third organic layers 115, 117, and 119 from overflowing to the pad area PAD.

A third inorganic encapsulation layer 138, a fourth inorganic encapsulation layer 140, a second organic encapsulation layer 142, and a protective layer 141 can be disposed above the second inorganic encapsulation layer 137. The third inorganic encapsulation layer 138, the fourth inorganic encapsulation layer 140, the second organic encapsulation layer 142, and the protective layer 141 can be formed up to an outer area of an overcoat layer 147.

Referring to FIG. 5, the touch layer 139 can include first and second touch metal layers TM1 and TM2. The first touch metal layer TM1 can be disposed on the third inorganic encapsulation layer 138. The second touch metal layer TM2 can be connected to the first touch metal layer TM1 through a contact hole of the second organic encapsulation layer 142.

The protective layer 141 can be disposed above the second touch metal layer TM2 to protect the second touch metal layer TM2.

The black matrix 143 and the overcoat layer 145 can be disposed above the protective layer 141. The overcoat layer 145 can be disposed to an outer area of the black matrix 143.

In order to dispose as many wirings and sub-pixels as possible within a limited space in the display device, a structure in which two or more organic layers having a flattening function are stacked is used. Accordingly, a connection electrode is disposed and used between the organic layer located at the bottom and the organic layer located at the top to connect the thin film transistor and the anode. However, when one organic layer is disposed on the connection electrode, there is a problem in that the organic layer above the connection electrode is not completely flattened. In this case, when the organic layer above the connection electrode is not completely flattened, the anode also has a problem that it is not flattened. In this case, when a step occurs in the anode, the distortion phenomenon of light due to the external light can occur. In this case, the moiré phenomenon can occur due to the light interference phenomenon caused by the mutual interference between the regular pattern shape of reflected light and the regularly disposed anode. This moiré phenomenon affects the image quality characteristics, and a persistent pattern phenomenon can remain, causing the problem of visibility. The moiré phenomenon is expressed as a rainbow moiré phenomenon under the external light, further reducing visibility.

To suppress this, the structure in which a plurality of organic layers is stacked vertically above the connection electrode can be considered. For example, when the plurality of organic layers are stacked vertically between the connection electrode and the anode electrode, the distance between the connection electrode and the anode electrode increases, and the thickness of the plurality of organic layers can be secured sufficiently thick, so the step problem of the anode can be resolved. However, as the total volume of the organic layer increases, outgassing occurring in the organic layer can become excessive. In this case, the pixel shrinkage problem can occur due to the outgassing.

Accordingly, in the display device 10 according to an example embodiment of the present disclosure, the second organic layer 117 and the third organic layer 119 are disposed on the same planar surface as each other on the first organic layer 115. In this case, the third organic layer 119 can be disposed to overlap the anode 121, and the second organic layer 117 can be disposed to surround a side surface of the second organic layer. In this case, the third organic layer 119 can be made of a material having a lower viscosity or a higher curing temperature than the first organic layer 115 and the second organic layer 117. When a material having a lower viscosity or a higher curing temperature is applied, the flatness can increase. Therefore, in the display device 10 according to an example embodiment of the present disclosure, the moiré phenomenon, such as the rainbow moiré (mura), which deteriorates the display quality, can be improved. In addition, only the third organic layer 119 can be disposed between the anode 121 and the connection electrode 186 to minimize or reduce the outgassing occurring in the organic layers and suppress the pixel shrinkage problem. However, without being limited thereto, only the second organic layer 117 can be disposed under the anode 121 which is disposed in an outer area connected to the pad PAD of the display device 10.

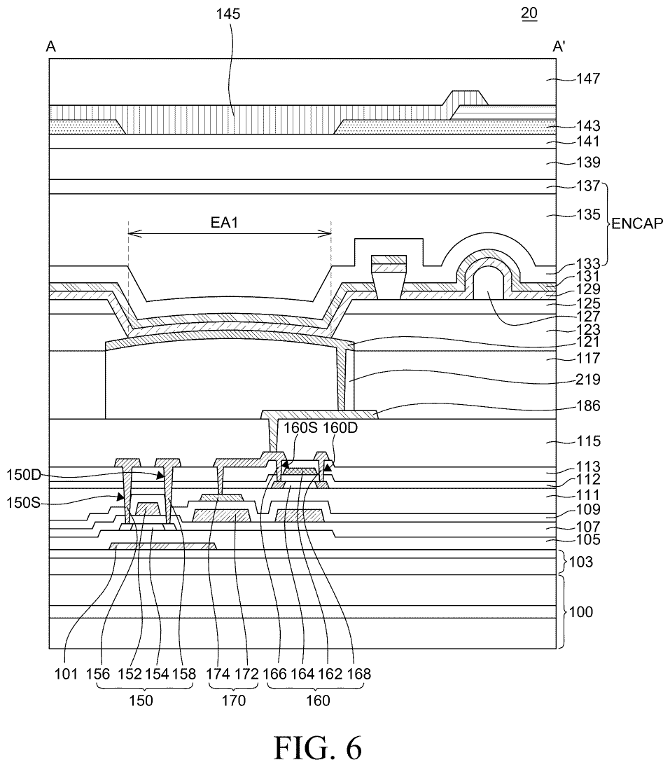

FIG. 6 is a cross-sectional view of an organic light emitting display device according to another example embodiment of the present disclosure. Compared to the display device 10 of FIGS. 1 to 5, a display device 20 of FIG. 6 differs mainly from a third planarization layer 219, and other components are substantially the same, and therefore, redundant descriptions thereof will be omitted or briefly provided.

Referring to FIG. 6, the third organic layer 219 can be disposed under the anode 121. The third organic layer 219 can have a planarization shape with a convex top surface. Accordingly, the top surface of the anode 121 can also have the same convex shape as the third organic layer 219.

In the display device 20 according to another example embodiment of the present disclosure, the top surface of the third organic layer 219 can have a convex shape. Accordingly, the anode 121 disposed on the third organic layer 219 can also have a convex shape. In this way, since the top surface of the anode 121 has a convex shape, there can be an effect of improving the reflection characteristics and color viewing angle by inducing diffuse reflection of light.

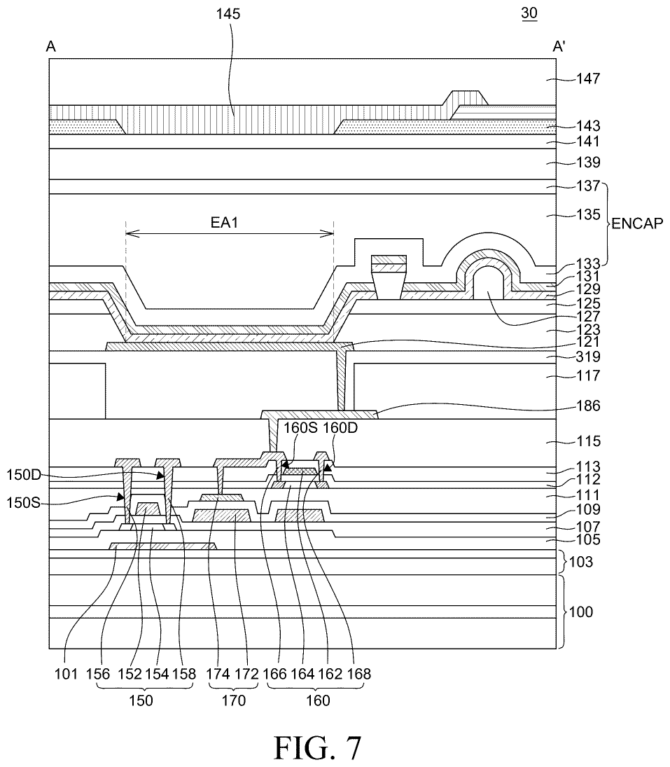

FIG. 7 is a cross-sectional view of an organic light emitting display device according to another example embodiment of the present disclosure. Compared to the display device 10 of FIGS. 1 to 5, a display device 30 of FIG. 7 differs mainly from a third planarization layer 319, and other components are substantially the same, and therefore, redundant descriptions thereof will be omitted or briefly provided.

Referring to FIG. 7, the third organic layer 319 can be disposed above the first organic layer 115 and the second organic layer 117 and under the anode 121. However, a thickness of the third organic layer 319 above the second organic layer 117 and a thickness of the third organic layer 319 under the anode 121 can be different. For example, in an area overlapping with the anode 121, the third organic layer 319 can be disposed between the first organic layer 115 and the anode 121, and thus can be relatively thick. However, in the area not overlapping with the anode 121, the third organic layer 319 can be disposed between the second organic layer 117 and the first bank 123, and thus can be relatively thin.

In a display device 30 according to another example embodiment of the present disclosure, the third organic layer 319 can be disposed thickly under the anode 121, and disposed thinly above the second organic layer 117, thereby improving the flatness. For example, the anode 121 can be flattened, thereby improving the moiré phenomenon, such as the rainbow moiré (mura), which deteriorates the display quality. In addition, by minimizing the increase in the thickness of the organic layers disposed under the anode 121, it is possible to minimize or reduce the outgassing occurring in the organic layers, and suppress the pixel shrinkage problem.

The example embodiments of the present disclosure can also be described as follows:

According to an aspect of the present disclosure, there is provided a display device. The display device includes a substrate including a display area and a non-display area, the display area including a plurality of sub-pixels, a first transistor disposed on the substrate in the plurality of sub-pixels, a first organic layer disposed on the first transistor, a connection electrode disposed on the first organic layer and connected to the first transistor, a second organic layer and a third organic layer disposed on the first organic layer and the connection electrode and a light emitting element disposed on the second organic layer and the third organic layer and including an anode connected to the connection electrode, an organic layer, and a cathode. The third organic layer overlaps the anode. The second organic layer is disposed to surround a side surface of the third organic layer.

The third organic layer can be made of a material having a lower viscosity or a higher curing temperature than those of the first organic layer and the second organic layer.

The third organic layer can be disposed between the anode and the connection electrode.

The thicknesses of portions of the third organic layer above the second organic layer can be different from thicknesses of other portions of the third organic layer under the anode.

The anode can overlap at least a portion of the connection electrode.

Some of the connection electrodes can overlap the second organic layer, and the other portions can overlap the third organic layer.

The third organic layer can include a first part surrounded by the second organic layer and a second part disposed on the second organic layer and the first part.

The third organic layer can have a flattened shape with a convex top surface.

The display device can further include an encapsulation part disposed on the light emitting element, a touch part disposed on the encapsulation part and a color filter part disposed on the touch part.

The color filter part can include an insulating layer disposed on the touch part, a black matrix disposed on the insulating layer to areas correspond between the plurality of light emitting elements and a color filter disposed on the insulating layer to correspond to the plurality of light emitting elements.

The display device can further include a first bank disposed on the second organic layer and the third organic layer to cover an end of the anode.

A light emitting area defined by adjacent first banks can have a circular shape.

The display device can further include a second bank disposed on the first bank.

The first bank can include a black material and the second bank can include a transparent material.

An end of the second bank can be disposed on an inclined side surface of the first bank.

An end of the first bank can be closer to a central portion of the anode than an end of the second bank.

An inclination angle of a side surface of the first bank can be smaller than that of a side surface of the second bank.

The display device can further include a plurality of spacers disposed on the second bank. The plurality of spacers can include a spacer having a regular taper shape and spacer having an inverted taper shape.

The first bank can include a transparent material or a black material.

The display device can further include a second transistor disposed on the plurality of sub-pixels on the substrate. An active layer of the first transistor can include an oxide semiconductor. An active layer of the second transistor can include a polycrystalline semiconductor.

A display panel can be provided according to an example embodiment of the present disclosure, the display panel is divided into a display area including a plurality of sub-pixels and a non-display area, the display panel comprising: a first transistor disposed in the plurality of sub-pixels; a first organic layer disposed on the first transistor; a connection electrode disposed on the first organic layer and connected to the first transistor; a second organic layer and a third organic layer disposed on the first organic layer and the connection electrode; and a light emitting element disposed on the second organic layer and the third organic layer and including an anode connected to the connection electrode, an organic layer, and a cathode, wherein the third organic layer overlaps the anode, and wherein the second organic layer is disposed to surround a side surface of the third organic layer.

Although the example embodiments of the present disclosure have been disclosed hereinabove, it can be understood by those skilled in the art that the present disclosure can be variously modified and altered without departing from the scope and spirit of the present disclosure described in the following claims.

What is claimed is:

1. A display device, comprising:
a substrate including a display area and a non-display area, the display area including a plurality of sub-pixels;
a first transistor disposed in the plurality of sub-pixels on the substrate;
a first organic layer disposed on the first transistor;
a connection electrode disposed on the first organic layer and connected to the first transistor;
a second organic layer and a third organic layer disposed on the first organic layer and the connection electrode; and
a light emitting element disposed on the second organic layer and the third organic layer, and including an anode connected to the connection electrode, an organic layer, and a cathode,
wherein the third organic layer overlaps the anode of the light emitting element, and
wherein the second organic layer is disposed to surround a side surface of the third organic layer.

2. The display device according to claim 1, wherein the third organic layer includes a material having a lower viscosity or a higher curing temperature than that of the first organic layer and/or the second organic layer.

3. The display device according to claim 1, wherein the third organic layer is disposed between the anode of the light emitting element and the connection electrode.

4. The display device according to claim 1, wherein thicknesses of portions of the third organic layer above the second organic layer are different from thicknesses of other portions of the third organic layer under the anode of the light emitting element.

5. The display device according to claim 1, wherein the anode of the light emitting element overlaps at least a portion of the connection electrode.

6. The display device according to claim 1, wherein some portions of the connection electrode overlap the second organic layer, and other portions of the connection electrode overlap the third organic layer.

7. The display device according to claim 1, wherein the third organic layer includes:
a first part surrounded by the second organic layer; and
a second part disposed on the second organic layer and the first part.

8. The display device according to claim 1, wherein the third organic layer includes a flattened shape with a convex top surface.

9. The display device according to claim 1, further comprising:
an encapsulation part disposed on the light emitting element;
a touch part disposed on the encapsulation part; and
a color filter part disposed on the touch part.

10. The display device according to claim 9, wherein the color filter part includes:
an insulating layer disposed on the touch part;
a black matrix disposed on the insulating layer to correspond areas between a plurality of light emitting elements; and
a color filter disposed on the insulating layer to correspond to the plurality of light emitting elements.

11. The display device according to claim 1, further comprising:
a first bank disposed on the second organic layer and the third organic layer to cover an end portion of the anode of the light emitting element.

12. The display device according to claim 11, wherein a light emitting area defined by adjacent first banks has a circular shape.

13. The display device according to claim 11, further comprising:
a second bank disposed on the first bank.

14. The display device according to claim 13, wherein the first bank includes a black material, and
the second bank includes a transparent material.

15. The display device according to claim 13, wherein an end portion of the second bank is disposed on the first bank.

16. The display device according to claim 13, wherein an end portion of the second bank is disposed on an inclined side surface of the first bank.

17. The display device according to claim 13, wherein an end portion of the first bank is closer to a central portion of the anode of the light emitting element than an end portion of the second bank.

18. The display device according to claim 13, wherein an inclination angle of a side surface of the first bank is smaller than an inclination angle of a side surface of the second bank.

19. The display device according to claim 13, further comprising:
a plurality of spacers disposed on the second bank,
wherein the plurality of spacers include a spacer having a taper shape and spacer having an inverted taper shape.

20. The display device according to claim 11, wherein the first bank includes a transparent material or a black material.

21. The display device according to claim 1, further comprising:
a second transistor disposed in the plurality of sub-pixels on the substrate,
wherein an active layer of the first transistor includes an oxide semiconductor, and
wherein an active layer of the second transistor includes a polycrystalline semiconductor.

22. A display panel, comprising:
a display area including a plurality of sub-pixels and a non-display area;
a first transistor disposed in the plurality of sub-pixels;
a first organic layer disposed on the first transistor;
a connection electrode disposed on the first organic layer and connected to the first transistor;
a second organic layer and a third organic layer disposed on the first organic layer and the connection electrode; and
a light emitting element disposed on the second organic layer and the third organic layer, and including an anode connected to the connection electrode,
wherein the third organic layer overlaps the anode of the light emitting element, and
wherein the second organic layer is disposed to surround a side surface of the third organic layer.
